(19) United States
(12) Patent Application Publication
(10) Pub. No.: US 2025/0004925 A1
(43) Pub. Date: Jan. 2, 2025

(54) GENERATING SIMULATION ENVIRONMENTS FOR TESTING AV BEHAVIOUR

(71) Applicant: Five AI Limited, Cambridge (GB)

(72) Inventor: Russell Darling, Cambridge (GB)

(73) Assignee: Five AI Limited, Cambridge (GB)

(21) Appl. No.: 18/274,167

(22) PCT Filed: Jan. 28, 2022
(86) PCT No.: PCT/EP2022/052123

§ 371 Date: Jul. 25, 2023

(30) Foreign Application Priority Data
Jan. 29, 2021 (GB) 2101233.1

(51) Int. Cl. G06F 11/36; G06F 11/34

(52) U.S. Cl. CPC G06F 11/3684; G06F 11/3457; G06F 11/3664; G06F 11/3696

(57) ABSTRACT

A computer implemented method of generating a scenario to be run in a simulation environment for testing the behaviour of an autonomous vehicle includes rendering, on a display of a computer device, an image of a static scene topology; and rendering on the display an object editing node comprising a set of input fields for receiving user input. The object editing node is for parameterizing an interaction of a challenger object relative to an ego object; and the method includes receiving into the input fields of the object editing node user input defining at least one temporal or relational constraint of the challenger object relative to the ego object. The at least one temporal or relational constraints define an interaction point of a defined interaction stage between the ego object and the challenger object. The method includes storing the set of constraints and defined interaction stage in an interaction container in a computer memory of the computer system; and generating a scenario to be run in a simulation environment, the scenario comprising the defined interaction stage executed on the static scene topology at the interaction point.

### TECHNICAL FIELD

The present disclosure relates to the generation of scenarios for use in simulation environments for testing the behaviour of autonomous vehicles.

### BACKGROUND

There have been major and rapid developments in the field of autonomous vehicles. An autonomous vehicle is a vehicle which is equipped with sensors and control systems which enabled it to operate without a human controlling its behaviour. An autonomous vehicle is equipped with sensors which enable it to perceive its physical environment, such sensors including for example cameras, RADAR and LiDAR. Autonomous vehicles are equipped with suitably programmed computers which are capable of processing data received from the sensors and making safe and predictable decisions based on the context which has been perceived by the sensors. There are different facets to testing the behaviour of the sensors and control systems aboard a particular autonomous vehicle, or a type of autonomous vehicle.

Sensor processing may be evaluated in real-world physical facilities. Similarly, the control systems for autonomous vehicles may be tested in the physical world, for example by repeatedly driving known test routes, or by driving routes with a human on-board to manage unpredictable or unknown context.

Physical world testing will remain an important factor in the testing of autonomous vehicles' capability to make safe and predictable decisions. However, physical world testing is expensive and time-consuming. Increasingly there is more reliance placed on testing using simulated environments. If there is to be an increase in testing in simulated environments, it is desirable that such environments can reflect as far as possible real-world scenarios. Autonomous vehicles need to have the facility to operate in the same wide variety of circumstances that a human driver can operate in. Such circumstances can incorporate a high level of unpredictability.

It is not viable to achieve from physical testing a test of the behaviour of an autonomous vehicle in all possible scenarios that it may encounter in its driving life. Increasing attention is being placed on the creation of simulation environments which can provide such testing in a manner that gives confidence that the test outcomes represent potential real behaviour of an autonomous vehicle.

For effective testing in a simulation environment, the autonomous vehicle under test (the ego vehicle) has knowledge of its location at any instant of time, understands its context (based on simulated sensor input) and can make safe and predictable decisions about how to navigate its environment to reach a pre-programmed destination.

Simulation environments need to be able to represent real-world factors that may change. This can include weather conditions, road types, road structures, road layout, junction types etc. This list is not exhaustive, as there are many factors that may affect the operation of an ego vehicle.

The present disclosure addresses the particular challenges which can arise in simulating the behaviour of actors in the simulation environment in which the ego vehicle is to operate. Such actors may be other vehicles, although they could be other actor types, such as pedestrians, animals, bicycles et cetera.

A simulator is a computer program which when executed by a suitable computer enables a sensor equipped vehicle control module to be developed and tested in simulation, before its physical counterpart is built and tested. A simulator provides a sensor simulation system which models each type of sensor with which the autonomous vehicle may be equipped. A simulator also provides a three-dimensional environmental model which reflects the physical environment that an automatic vehicle may operate in. The 3-D environmental model defines at least the road network on which an autonomous vehicle is intended to operate, and other actors in the environment. In addition to modelling the behaviour of the ego vehicle, the behaviour of these actors also needs to be modelled.

Simulators generate test scenarios (or handle scenarios provided to them). As already explained, there are reasons why it is important that a simulator can produce many different scenarios in which the ego vehicle can be tested. Such scenarios can include different behaviours of actors. The large number of factors involved in each decision to which an autonomous vehicle must respond, and the number of other requirements imposed on those decisions (such as safety and comfort as two examples) mean it is not feasible to write a scenario for every single situation that needs to be tested. Nevertheless, attempts must be made to enable simulators to efficiently provide as many scenarios as possible, and to ensure that such scenarios are close matches to the real world. If testing done in simulation does not generate outputs which are faithful to the outputs generated in the corresponding physical world environment, then the value of simulation is markedly reduced.

Scenarios may be created from live scenes which have been recorded in real life driving. It may be possible to mark such scenes to identify real driven paths and use them for simulation. Test generation systems can create new scenarios, for example by taking elements from existing scenarios (such as road layout and actor behaviour) and combining them with other scenarios. Scenarios may additionally or alternatively be randomly generated.

However, there is increasingly a requirement to tailor scenarios for particular circumstances such that particular sets of factors can be generated for testing. It is desirable that such scenarios may define actor behaviour.

### SUMMARY

One aspect of the present disclosure addresses such challenges. According to one aspect of the invention, there is provided a computer implemented method of generating a scenario to be run in a simulation environment for testing the behaviour of an autonomous vehicle, the method comprising:
rendering on a display of a computer device, an image of a static scene topology;
rendering on the display an object editing node comprising a set of input fields for receiving user input, the object editing node for parameterizing an interaction of a challenger object relative to an ego object;
receiving into the input fields of the object editing node user input defining at least one temporal or relational constraint of the challenger object relative to the ego object, the at least one temporal or relational constraints defining an interaction point of a defined interaction stage between the ego object and the challenger object;
storing the set of constraints and defined interaction stage in an interaction container in a computer memory of the computer system; and
generating a scenario to be run in a simulation environment, the scenario comprising the defined interaction stage executed on the static scene topology at the interaction point.

The system may be configured such that the set of input fields comprises a field for receiving an indication of a defined interaction for the challenger object to execute in the scenario.

The system may then be further configured such that the set of input fields comprises an input field for receiving an indication of the manner in which the defined interaction is to be executed in the scenario.

The system may be configured such that the set of input fields comprises a field for receiving an indication of a behavior of the challenger object at the interaction point.

The system may be configured such that the set of input fields comprises a field for receiving an indication of an object type.

The system may be configured such that one or more of the input fields comprises a menu of predetermined options, enabling selection by a user of one of the predetermined options to parameterize the challenger object.

The system may be configured such that the static scene topology comprises a road layout.

The method may further comprise the step of selecting a static scene topology from a library of predefined scene topologies and rendering the selected scene topology on the display.

The system may be configured such that the road layout comprises one or more driving lane, and wherein the set of input fields comprises a field for receiving an indication of lane driving behavior of the challenger object.

The method may further comprise assigning lane identifiers to each of the one or more driving lane of the road layout and receiving an association via the object editing node of an identified lane and the challenger object at the interaction point.

The method may further comprise rendering on the display a second object editing node for further parameterizing the challenger object and receiving user input into fields of the second editing node to define a further stage of the defined interaction each interaction defined as a respective sequence of stages, wherein the generated scenario comprises the sequence of interaction stages executed by the challenger object.

The method may further comprise rendering on the display an ego object editing node for parameterizing the ego vehicle in the scenario by receiving a starting condition of the ego vehicle and behaviour constraints for the ego vehicle prior to the interaction point.

The system may be configured such that the challenger object comprises a dynamic actor, wherein the interaction defines an action to be taken by the dynamic actor at a time and location in the scene relative to the ego vehicle defined by the at least one temporal or relational constraint.

The system may then be further configured such that the action to be taken by the challenger object comprises a manoeuvre or behaviour.

The method may further comprise storing the interaction container with an interaction container identifier which identifies the defined interaction and the scene topology.

The manoeuvre may comprise one of: cut-in, cut-out, and switch lanes.

The behaviour may comprise one of: deceleration, acceleration, follow lane, and travel at fixed speed.

According to another aspect of the invention there is provided a computer system for generating a scenario to be run in a simulation environment for testing the behaviour of an autonomous vehicle, the system comprising:
computer memory;
a user interface configured to display an image of a static scene topology;
a processor configured to render on the user interface an object editing node comprising a set of input fields for receiving user input, the object editing node for parameterizing an interaction of a challenger object relative to an ego object;
the user interface configured to receive into the input fields of the object editing node user input defining at least one temporal or relational constraint of the challenger object relative to the ego object, the at least one temporal or relational constraints defining an interaction point of a defined interaction stage between the ego object and the challenger object;
the processor configured to store the at least one constraint and defined interaction stage in an interaction container in the computer memory of the computer system; and
to generate a scenario to be run in a simulation environment, the scenario comprising the defined interaction stage executed on the static scene topology at the interaction point.

There is also provided a computer readable media, which may be transitory or non-transitory, on which is stored computer readable instructions which when executed by one or more processor carry out any of the predefined methods.

### BRIEF DESCRIPTION OF THE DRAWINGS

For a better understanding of the present invention and to show how the same may be carried into effect, reference will now be made by way of example to the accompanying drawings.

FIG. 1 shows a diagram of the interaction space of a simulation containing 3 vehicles.

FIG. 2 shows a graphical representation of a cut-in manoeuvre performed by an actor vehicle.

FIG. 3 shows a graphical representation of a cut-out manoeuvre performed by an actor vehicle.

FIG. 4 shows a graphical representation of a slow-down manoeuvre performed by an actor vehicle.

FIG. 5 shows a highly schematic block diagram of a computer implementing a scenario builder.

FIG. 6 shows a highly schematic block diagram of a runtime stack for an autonomous vehicle.

FIG. 7 shows a highly schematic block diagram of a testing pipeline for an autonomous vehicle's performance during simulation.

FIG. 8 shows a graphical representation of a pathway for an exemplary cut-in manoeuvre.

FIG. 9a shows a first exemplary user interface for configuring the dynamic layer of a simulation environment according to a first embodiment of the invention.

FIG. 9b shows a second exemplary user interface for configuring the dynamic layer of a simulation environment according to a second embodiment of the invention.

FIG. 10a shows a graphical representation of the exemplary dynamic layer configured in FIG. 9a, wherein the TV1 node has been selected.

FIG. 10b shows a graphical representation of the exemplary dynamic layer configured in FIG. 9a, wherein the TV2 node has been selected.

FIG. 11 shows a graphical representation of the dynamic layer configured in FIG. 9a, wherein no node has been selected.

FIG. 12 shows a generic user interface wherein the dynamic layer of a simulation environment may be parametrised.

FIG. 13 shows an exemplary user interface wherein the static layer of a simulation environment may be parametrised.

FIG. 14a shows an exemplary user interface comprising features configured to allow and control a dynamic visualisation of the scenario parametrised in FIG. 9b; FIG. 14a shows the scenario at the start of the first manoeuvre.

FIG. 14b shows the same exemplary user interface as in FIG. 14a, wherein time has passed since the instance of FIG. 14a, and the parametrised vehicles have moved to reflect their new positions after that time; FIG. 14b shows the scenario during the parametrised manoeuvres.

FIG. 14c shows the same exemplary user interface as in FIGS. 14a and 14b, wherein time has passed since the instance of FIG. 14b, and the parametrised vehicles have moved to reflect their new positions after that time; FIG. 14c shows the scenario at the end of the parametrised manoeuvres.

FIG. 15a shows a highly schematic diagram of a process for linking a parametrised road layout on a map.

FIG. 15b shows a map on which the overlays represent the instances of a parametrised road layout identified on the map in the process represented by FIG. 15a.

### DETAILED DESCRIPTION

It is necessary to define scenarios which can be used to test the behaviour of an ego vehicle in a simulated environment. Scenarios are defined and edited in offline mode, where the ego vehicle is not controlled, and then exported for testing in the next stage of a testing pipeline 7200 which is described below.

A scenario comprises one or more agents (sometimes referred to as actors) travelling along one or more paths in a road layout. A road layout is a term used herein to describe any features that may occur in a driving scene and, in particular, includes at least one track along which a vehicle is intended to travel in a simulation. That track may be a road or lane or any other driveable path. A road layout is displayed in a scenario to be edited as an image on which agents are instantiated. According to embodiments of the present invention, road layouts, or other scene topologies, are accessed from a database of scene topologies. Road layouts have lanes etc. defined in them and rendered in the scenario. A scenario is viewed from the point of view of an ego vehicle operating in the scene. Other agents in the scene may comprise non-ego vehicles or other road users such as cyclists and pedestrians. The scene may comprise one or more road features such as roundabouts or junctions. These agents are intended to represent real-world entities encountered by the ego vehicle in real-life driving situations. The present description allows the user to generate interactions between these agents and the ego vehicle which can be executed in the scenario editor and then simulated.

The present description relates to a method and system for generating scenarios to obtain a large verification set for testing an ego vehicle. The scenario generation scheme described herein enables scenarios to be parametrised and explored in a more user-friendly fashion, and furthermore enables scenarios to be reused in a closed loop.

In the present system, scenarios are described as a set of interactions. Each interaction is defined relatively between actors of the scene and a static topology of the scene. Each scenario may comprise a static layer for rendering static objects in a visualisation of an environment which is presented to a user on a display, and a dynamic layer for controlling motion of moving agents in the environment. Note that the terms “agent” and “actor” may be used interchangeably herein.

Each interaction is described relatively between actors and the static topology. Note that in this context, the ego vehicle can be considered as a dynamic actor. An interaction encompasses a manoeuvre or behaviour which is executed relative to another actor or a static topology.

In the present context, the term “behaviour” may be interpreted as follows. A behaviour owns an entity (such as an actor in a scene). Given a higher-level goal, a behaviour yields manoeuvres interactively which progress the entity towards the given goal. For example, an actor in a scene may be given a Follow Lane goal and an appropriate behavioural model. The actor will (in the scenario generated in an editor, and in the resulting simulation) attempt to achieve that goal.

Behaviours may be regarded as an opaque abstraction which allow a user to inject intelligence into scenarios resulting in more realistic scenarios. By defining the scenario as a set of interactions, the present system enables multiple actors to co-operate together with active behaviours to create a closed loop behavioural network akin to a traffic model.

The term “manoeuvre” may be considered in the present context as the concrete physical action which an entity may exhibit to achieve its particular goal following its behavioural model.

An interaction encompasses the conditions and specific manoeuvre (or set of manoeuvres)/behaviours with goals which occur relatively between two or more actors and/or an actor and the static scene.

According to features of the present system, interactions may be evaluated after the fact using temporal logic. Interactions may be seen as reusable blocks of logic for sequencing scenarios, as more fully described herein.

Using the concept of interactions, it is possible to define a “critical path” of interactions which are important to a particular scenario. Scenarios may have a full spectrum of abstraction for which parameters may be defined. Variations of these abstract scenarios are termed scenario instances.

Scenario parameters are important to define a scenario, or interactions in a scenario. The present system enables any scenario value to be parametrised. Where a value is expected in a scenario, a parameter can be defined with a compatible parameter type and with appropriate constraints, as discussed further herein when describing interactions.

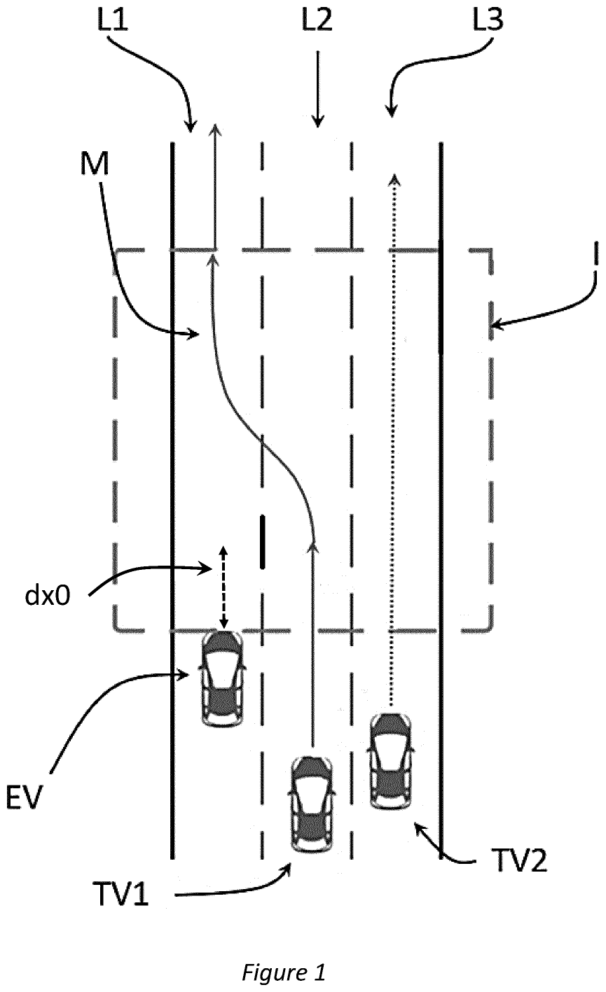

Reference is made to FIG. 1 to illustrate a concrete example of the concepts described herein. An ego vehicle EV is instantiated on a Lane L1. A challenger actor TV1 is initialised and according to the desired scenario is intended to cut in relative to the ego vehicle EV. The interaction which is illustrated in FIG. 1 is to define a cut-in manoeuvre which occurs when the challenger actor TV1 achieves a particular relational constraint relative to the ego vehicle EV. In FIG. 1, the relational constraint is defined as a lateral distance (dy0) offset condition denoted by the dotted line dx0 relative to the ego vehicle. At this point, the challenger vehicle TV 1 performs a Switch Lane manoeuvre which is denoted by arrow M ahead of the ego vehicle EV. The interaction further defines a new behaviour for the challenger vehicle after its cut in manoeuvre, in this case, a Follow Lane goal. Note that this goal is applied to Lane L1 (whereas previously the challenger vehicle may have had a Follow Lane goal applied to Lane L2). A box defined by a broken line designates this set of manoeuvres as an interaction I. Note that a second actor vehicle TV2 has been assigned a Follow Lane goal to follow Lane L3.

The following parameters may be assigned to define the interaction:
object—an abstract object type which could be filled out from any ontology class;
longitude Distance dx0—distance measured longitudinally to a lane;
lateral distance dy0—distance measured laterally to a lane;
velocity Ve, Vy—speed assigned to object (in longitudinal or lateral directions);
acceleration Gx—acceleration assigned to object;
lane—a topological descriptor of a single lane.

An interaction is defined as a set of temporal and relational constraints between the dynamic and static layers of a scenario. The dynamic layers represent scene objects and their states, and the static layers represent scene topology of a scenario. The constraints parameterizing the layers can be both monitored at runtime or described and executed at design time, while a scenario is being edited/authored.

Examples of interactions are given in the following table, Table 1.

| Interaction | Summary | Relationships |
|---|---|---|
| Cutin | An object moves | 1. Object <> Lane(Ego) |
| | laterally from adjacent | 2. Object <> Trajectory(Ego) |
| | lane into ego lane and | |
| | intersects with near | |
| | trajectory | |
| CutOut | An object moves | 1. Object <> Lane(Ego) |
| | laterally out from ego | 2. Object <> Trajectory(Ego) |
| | lane and near trajectory | |
| | intersection to adjacent | |
| | lane | |
| Obstruct | An object is in ego lane | 1. Object <> Lane(Ego) |
| | and intersects with near | 2. Object <> Trajectory(Ego) |
| | trajectory | |
| FollowLane | An object has kinematic | 1. Object <> Lane |
| | motion longitudinally | |
| | along a lane | |
| InLane | An object is within a | 1. Object <> Lane |
| | lane | |

Each interaction has a summary which defines that particular interaction, and the relationships involved in the interaction. For example, a “cut-in” interaction as illustrated in FIG. 1 is an interaction in which an object (the challenger actor) moves laterally from an adjacent lane into the ego lane and intersects with a near trajectory. A near trajectory is one that overlaps with another actor, even if the other actor does not need to act in response.

There are two relationships for this interaction. The first is a relationship between the challenger actor and the ego lane, and the second is a relationship between the challenger actor and the ego trajectory. These relationships may be defined by temporal and relational constraints as discussed in more detail in the following.

The temporal and relational constraints of each interaction may be defined using one or more nodes to enter characterising parameters for the interaction. According to the present disclosure, nodes holding these parameters are stored in an interaction container for the interaction. Scenarios may be constructed by a sequence of interactions, by editing and connecting these nodes. These enable a user to construct a scenario with a set of required interactions that are to be tested in the runtime simulation without complex editing requirements. in prior systems, when generating and editing scenarios, a user needs to determine whether or not interactions which are required to be tested will actually occur in the scenario that they have created in the editing tool.

The system described herein enables a user who is creating and editing scenarios to define interactions which are then guaranteed to occur when a simulation is run. Thus, such interactions can be tested in simulation. As described above, the interactions are defined between the static topology and dynamic actors.

A user can define certain interaction manoeuvres, such as those given in the table above.

A user may define parameters of the interaction, or limit a parameter range in the interaction.

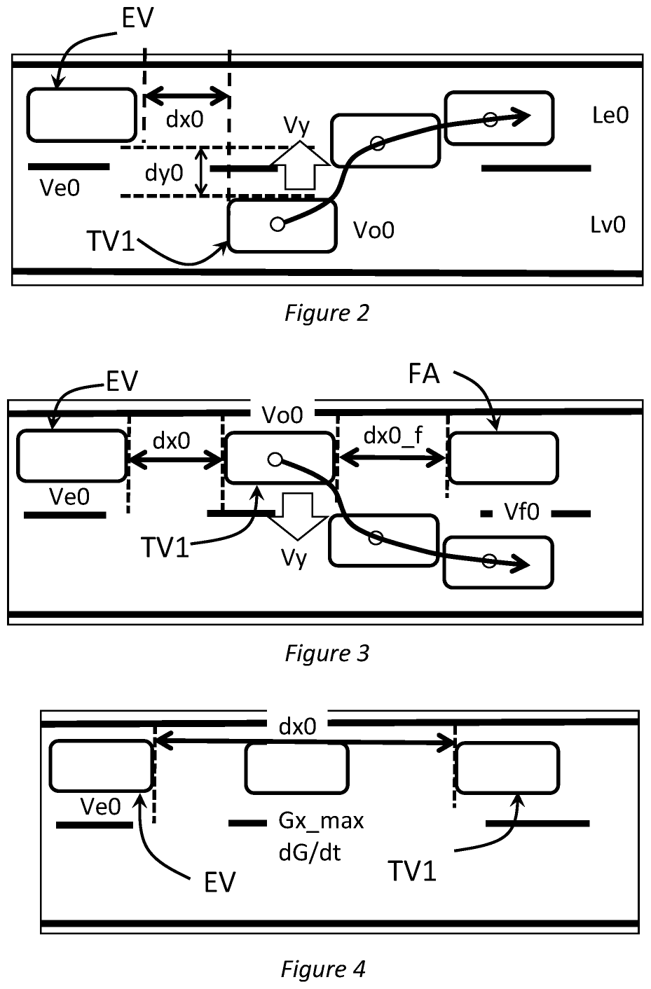

FIG. 2 shows an example of a cut-in manoeuvre. In this manoeuvre, the distance dx0 in longitude between the ego vehicle EV and the challenging vehicle TV1 can be set at a particular value or range of values. An inside lateral distance dy0 between the ego vehicle EV and the challenging vehicle TV1 may be set at a particular value or within a parameter range. A leading vehicle lateral motion (Vy) parameter may be set at a particular value or within a particular range. The lateral motion parameter my represent the cut in speed. A leading vehicle velocity (Vo0) which is the forward velocity of the challenging vehicle may be set as a particular defined value or within a parameter range. An ego velocity Ve0 may be set up at a particular value or within a parameter range, being the velocity of the ego vehicle in the forward direction. An ego lane (Le0) and leading vehicle lane (Lv0) may be defined in the parameter range.

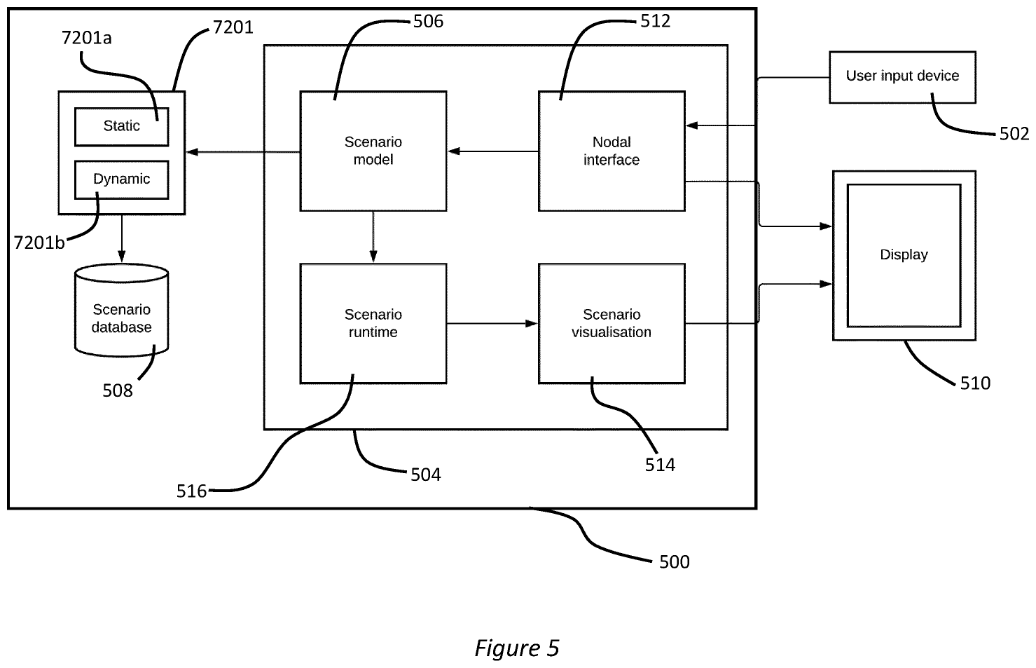

FIG. 3 is a diagram illustrating a cut-out interaction. This interaction has some parameters which have been identified above with reference to the cut-in interaction of FIG. 2. Note also that a forward vehicle is defined denoted FA (forward actor), and that there are additional parameters relating to this forward vehicle. These include distance in longitude forward direction (dx0_f) and velocity of the forward vehicle.

In addition, a vehicle velocity (Vf0) may be set up at a particular value or within a parameter range. The vehicle velocity Vf0 is a velocity of a forward vehicle ahead of the cut-out; note that in this case, the leading vehicle lateral motion Vy is motion in a cut-out direction rather than a cut-in direction. Note also that a forward vehicle is defined denoted FA (forward actor), and that there are additional parameters relating to this forward vehicle. These include distance in longitude forward direction (dx0_f) and velocity of the forward vehicle.

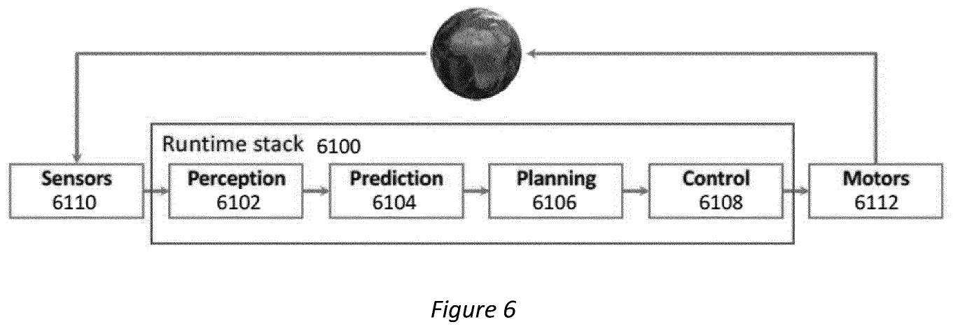

FIG. 4 illustrates a deceleration interaction. In this case, the parameters Ve0, dx0 and Vo0 have the same definitions as in the cut-in interaction. Values for these may be set specifically or within a parameter range. In addition, a maximum acceleration (Gx_max) may be set at a specific value or in a parameter range as the deceleration of the challenging actor.

The steps for defining an interaction are discussed in more detail in the following.

A user may set a configuration for the ego vehicle that captures target speed (e.g. proportion or a target speed for each speed limit zone of a road layout), maximum acceleration values, maximus jerk values etc. In some embodiments, a default speed may be applied for the ego vehicle as the speed limit for a particular speed limit zone of the road layout. A user may be allowed to override this default value with acceleration/jerk values, or set a start point and target speed for the ego vehicle at the interaction cut-in point. This could then be used to calculate the acceleration values between the start point and the cut-in point. As will be explained in more detail below, the editing tool allows a user to generate the scenario in the editing tool, and then to visualise it in such a way that they may adjust/explore the parameters that they have configured. The speed for the ego vehicle at the point of interaction may be referred to herein as the interaction point speed for ego vehicle.

An interaction point speed for the challenger vehicle may also be configured. A default value for the speed of the challenger vehicle may be set as a speed limit for the road, or to match the ego vehicle. In some circumstances, the ego vehicle may have a planning stack which is at least partially exposed in scenario runtime. Note that the latter option would apply in situations where the speed of the ego vehicle can be extracted from the stack in scenario runtime. A user is allowed to overwrite the default speed with acceleration/jerk values, or to set a start point and speed for the challenger vehicle and use this to calculate the acceleration values between start point and the cut-in point. As with the ego vehicle, when the generated scenario is run in the editing tool, a user can adjust/explore these values. In the interaction containers which are discussed herein (comprising the nodes), values for challenger vehicles may be configurable relative to the ego vehicle, so users can configure the speed/acceleration/jerk of the challenger vehicle to be relative to the ego vehicle values at the interaction point.

In the preceding, reference has been made to an interaction point. For each interaction, an interaction point is defined. For example, in the scenario of FIGS. 1 and 2, a cut-in interaction point is defined. In some embodiments, this is defined at the point at which the ego vehicle and the challenger vehicle have a lateral overlap (based on vehicle edges as a projected path for and aft; the lateral overlap could be a percent of this). If this cannot be determined, it could be estimated based on lane width, vehicle width, some lateral positioning.

The interaction is further defined relative to the scene topography by setting a start lane (L1 in FIG. 1) for the ego vehicle. For the challenger vehicle, a start lane (L2) and an end lane (L1) is set.

A cut-in gap may be defined. A time headway is the critical parameter value around which the rest of the cut-in interaction is constructed. If a user sets the cut-in point to be two seconds ahead of the ego vehicle, a distance for the cut-in gap is calculated using the ego vehicle target speed at the point of interaction. For example, at a speed of 50 miles an hour (22 m per second), a two second cut-in gap would set a cut-in distance of 44 meters.

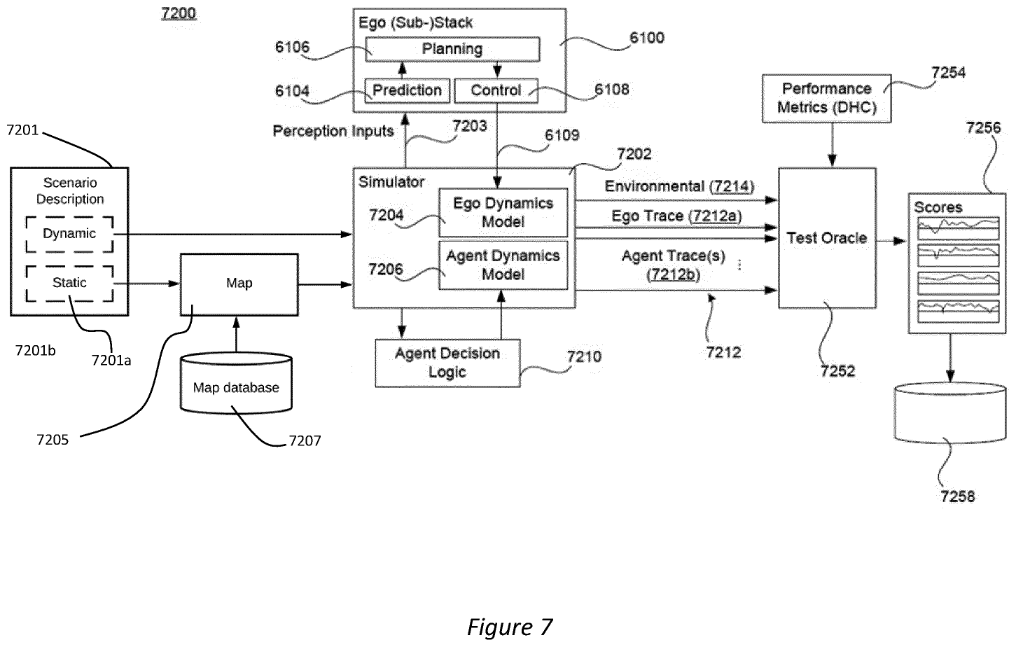

FIG. 5 shows a highly schematic block diagram of a computer implementing a scenario builder, which comprises a display unit 510, a user input device 502, computer storage such as electronic memory 500 holding program code 504, and a scenario database 508.

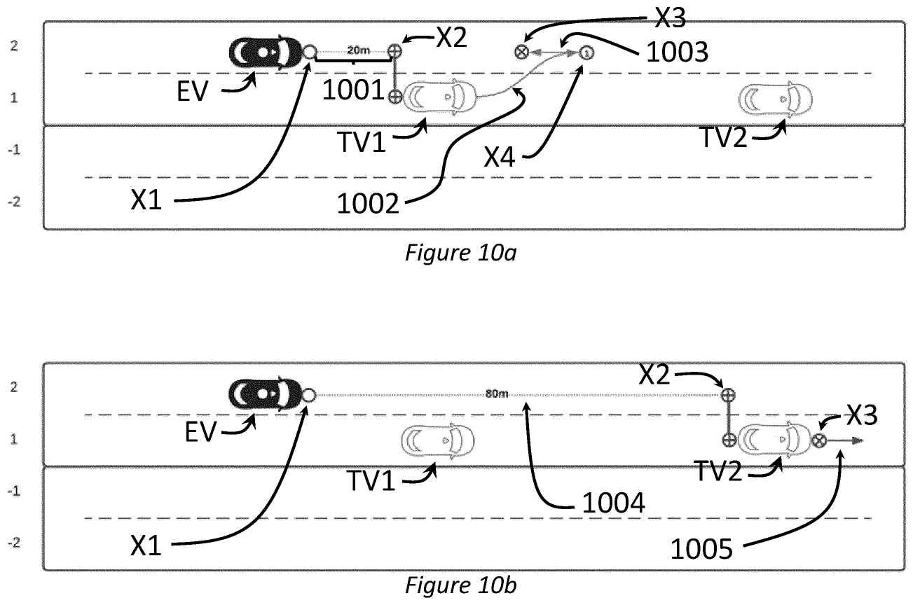

The program code 504 is shown to comprise four modules configured to receive user input and generate output to be displayed on the display unit 510. User input entered to a user input device 502 is received by a nodal interface 512 as described herein with reference to FIGS. 9-13. A scenario model module 506 is then configured to receive the user input from the nodal interface 512 and to generate a scenario to be simulated.

The scenario model data is sent to a scenario description module 7201, which comprises a static layer 7201a and a dynamic layer 7201b. The static layer 7201a includes the static elements of a scenario, which would typically include a static road layout, and the dynamic layer 7201b defines dynamic information about external agents within the scenario, such as other vehicles, pedestrians, bicycles etc. Data from the scenario model 506 that is received by the scenario description module 7201 may then be stored in a scenario database 508 from which the data may be subsequently loaded and simulated. Data from the scenario model 506, whether received via the nodal interface or the scenario database, is sent to the scenario runtime module 516, which is configured to perform a simulation of the parametrised scenario. Output data of the scenario runtime is then sent to the scenario visualisation module 514, which is configured to produce data in a format that can be read to produce a dynamic visual representation of the scenario. The output data of the scenario visualisation module 514 may then be sent to the display unit 510 whereupon the scenario can be viewed, for example in a video format. In some embodiments, further data pertaining to analysis performed by a program code module 512, 506, 516, 514 on the simulation data may also be displayed by the display unit 510.

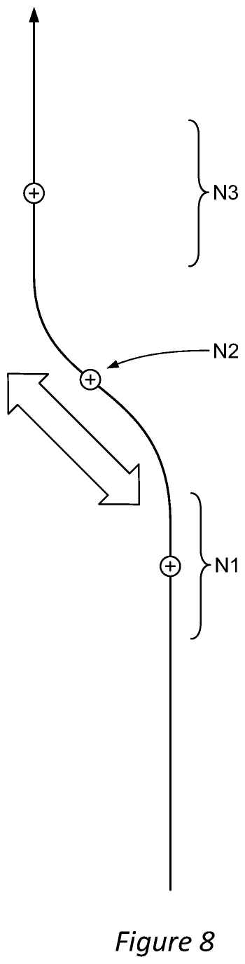

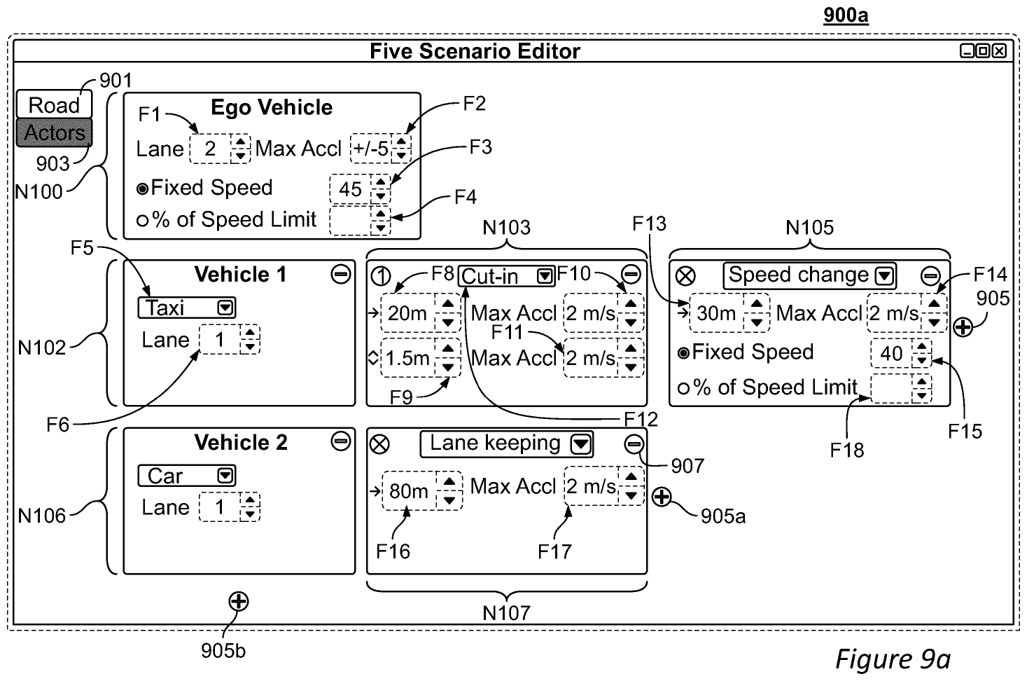

Reference will now be made to FIGS. 6 and 7 to describe a simulation system which can use scenarios created by the scenario builder described herein.

FIG. 6 shows a highly schematic block diagram of a runtime stack 6100 for an autonomous vehicle (AV), also referred to herein as an ego vehicle (EV). The run time stack 6100 is shown to comprise a perception system 6102, a prediction system 6104, a planner 6106 and a controller 6108.

In a real-world context, the perception system 6102 would receive sensor outputs from an on-board sensor system 6110 of the AV and uses those sensor outputs to detect external agents and measure their physical state, such as their position, velocity, acceleration etc. The on-board sensor system 6110 can take different forms but generally comprises a variety of sensors such as image capture devices (cameras/optical sensors), LiDAR and/or RADAR unit(s), satellite-positioning sensor(s) (GPS etc.), motion sensor(s) (accelerometers, gyroscopes etc.) etc., which collectively provide rich sensor data from which it is possible to extract detailed information about the surrounding environment and the state of the AV and any external actors (vehicles, pedestrians, cyclists etc.) within that environment. The sensor outputs typically comprise sensor data of multiple sensor modalities such as stereo images from one or more stereo optical sensors, LiDAR, RADAR etc. Stereo imaging may be used to collect dense depth data, with LiDAR/RADAR etc. proving potentially more accurate but less dense depth data. More generally, depth data collection from multiple sensor modalities may be combined in a way that preferably respects their respective levels of uncertainty (e.g. using Bayesian or non-Bayesian processing or some other statistical process etc.). Multiple stereo pairs of optical sensors may be located around the vehicle e.g. to provide full 360° depth perception.

The perception system 6102 comprises multiple perception components which co-operate to interpret the sensor outputs and thereby provide perception outputs to the prediction system 6104. External agents may be detected and represented probabilistically in a way that reflects the level of uncertainty in their perception within the perception system 6102.

In a simulation context, depending on the nature of the testing—and depending, in particular, on where the stack 6100 is sliced-it may or may not be necessary to model the on-board sensor system 6100. With higher-level slicing, simulated sensor data is not required therefore complex sensor modelling is not required.

The perception outputs from the perception system 6102 are used by the prediction system 6104 to predict future behaviour of external actors (agents), such as other vehicle in the vicinity of the AV.

Predictions computed by the prediction system 6104 are provided to the planner 6106, which uses the predictions to make autonomous driving decisions to be executed by the AV in a given driving scenario. A scenario is represented as a set of scenario description parameters used by the planner 6106. A typical scenario would define a drivable area and would also capture predicted movements of any external agents (obstacles, from the AV's perspective) within the drivable area. The driveable area can be determined using perception outputs from the perception system 6102 in combination with map information, such as an HD (high definition) map.

A core function of the planner 6106 is the planning of trajectories for the AV (ego trajectories) taking into account predicted agent motion. This may be referred to as manoeuvre planning. A trajectory is planned in order to carry out a desired goal within a scenario. The goal could, for example, be to enter a roundabout and leave it at a desired exit; to overtake a vehicle in front; or to stay in a current lane at a target speed (lane following). The goal may, for example, be determined by an autonomous route planner (not shown).

The controller 6108 executes the decisions taken by the planner 6106 by providing suitable control signals to an on-board actor system 6112 of the AV. In particular, the planner 6106 plans manoeuvres to be taken by the AV and the controller 6108 generates control signals in order to execute those manoeuvres.

FIG. 7 shows a schematic block diagram of a testing pipeline 7200. The testing pipeline 7200 is shown to comprise a simulator 7202 and a test oracle 7252. The simulator 7202 runs simulations for the purpose of testing all or part of an AV run time stack.

By way of example only, the description of the testing pipeline 7200 makes reference to the runtime stack 6100 of FIG. 6 to illustrate some of the underlying principles by example. As discussed, it may be that only a sub-stack of the run-time stack is tested, but for simplicity, the following description refers to the AV stack 6100 throughout; noting that what is actually tested might be only a subset of the AV stack 6100 of FIG. 6, depending on how it is sliced for testing. In FIG. 6, reference numeral 6100 can therefore denote a full AV stack or only sub-stack depending on the context.

FIG. 7 shows the prediction, planning and control systems 6104, 6106 and 6108 within the AV stack 6100 being tested, with simulated perception inputs 7203 fed from the simulator 7202 to the stack 6100. However, this does not necessarily imply that the prediction system 6104 operates on those simulated perception inputs 7203 directly (though that is one viable slicing, in which case the simulated perception inputs 7203 would correspond in form to the final outputs of the perception system 6102). Where the full perception system 6102 is implemented in the stack being tested (or, at least, where one or more lower-level perception components that operate on raw sensor data are included), then the simulated perception inputs 7203 would comprise simulated sensor data.

The simulated perception inputs 7203 are used as a basis for prediction and, ultimately, decision-making by the planner 6106. The controller 6108, in turn, implements the planner's decisions by outputting control signals 6109. In a real-world context, these control signals would drive the physical actor system 6112 of AV. The format and content of the control signals generated in testing are the same as they would be in a real-world context. However, within the testing pipeline 7200, these control signals 6109 instead drive the ego dynamics model 7204 to simulate motion of the ego agent within the simulator 7202.

To the extent that external agents exhibit autonomous behaviour/decision-making within the simulator 7202, some form of agent decision logic 7210 is implemented to carry out those decisions and drive external agent dynamics within the simulator 7202 accordingly. The agent decision logic 7210 may be comparable in complexity to the ego stack 6100 itself or it may have a more limited decision-making capability. The aim is to provide sufficiently realistic external agent behaviour within the simulator 7202 to be able to usefully test the decision-making capabilities of the ego stack 6100. In some contexts, this does not require any agent decision making logic 7210 at all (open-loop simulation), and in other contexts useful testing can be provided using relatively limited agent logic 7210 such as basic adaptive cruise control (ACC). Similar to the ego stack 6100, any agent decision logic 7210 is driven by outputs from the simulator 7202, which in turn are used to derive inputs to the agent dynamics models 7206 as a basis for the agent behaviour simulations.

As explained above, a simulation of a driving scenario is run in accordance with a scenario description 7201, having both static and dynamic layers 7201a, 7201b.

The static layer 7201a defines static elements of a scenario, which would typically include a static road layout. The static layer 7201a of the scenario description 7201 is disposed onto a map 7205, the map loaded from a map database 7207. For any defined static layer 7201a road layout, the system may be capable of recognising, on a given map 7205, all segments of that map 7205 comprising instances of the defined road layout of the static layer 7201a. For example, if a particular map were selected and a ‘roundabout’ road layout defined in the static layer 7201a, the system could find all instances of roundabouts on the selected map 7205 and load them as simulation environments.

The dynamic layer 7201b defines dynamic information about external agents within the scenario, such as other vehicles, pedestrians, bicycles etc. The extent of the dynamic information provided can vary. For example, the dynamic layer 7201b may comprise, for each external agent, a spatial path or a designated lane to be followed by the agent together with one or both motion data and behaviour data.

In simple open-loop simulation, an external actor simply follows a spatial path and motion data defined in the dynamic layer that is non-reactive i.e. does not react to the ego agent within the simulation. Such open-loop simulation can be implemented without any agent decision logic 7210.

However, in “closed-loop” simulation, the dynamic layer 7201b instead defines at least one behaviour to be followed along a static path or lane (such as an ACC behaviour). In this case, the agent decision logic 7210 implements that behaviour within the simulation in a reactive manner, i.e. reactive to the ego agent and/or other external agent(s). Motion data may still be associated with the static path but in this case is less prescriptive and may for example serve as a target along the path. For example, with an ACC behaviour, target speeds may be set along the path which the agent will seek to match, but the agent decision logic 7210 might be permitted to reduce the speed of the external agent below the target at any point along the path in order to maintain a target headway from a forward vehicle.

In the present embodiments, the static layer provides a road network with lane definitions that is used in place of defining ‘paths’. The dynamic layer contains the assignment of agents to lanes, as well as any lane manoeuvres, while the actual lane definitions are stored in the static layer.

The output of the simulator 7202 for a given simulation includes an ego trace 7212a of the ego agent and one or more agent traces 7212b of the one or more external agents (traces 7212).

A trace is a complete history of an agent's behaviour within a simulation having both spatial and motion components. For example, a trace may take the form of a spatial path having motion data associated with points along the path such as speed, acceleration, jerk (rate of change of acceleration), snap (rate of change of jerk) etc.

Additional information is also provided to supplement and provide context to the traces 7212. Such additional information is referred to as “environmental” data 7214 which can have both static components (such as road layout) and dynamic components (such as weather conditions to the extent they vary over the course of the simulation).

To an extent, the environmental data 7214 may be “passthrough” in that it is directly defined by the scenario description 7201 and is unaffected by the outcome of the simulation. For example, the environmental data 7214 may include a static road layout that comes from the scenario description 7201 directly. However, typically the environmental data 7214 would include at least some elements derived within the simulator 7202. This could, for example, include simulated weather data, where the simulator 7202 is free to change whether change weather conditions as the simulation progresses. In that case, the weather data may be time-dependent, and that time dependency will be reflected in the environmental data 7214.

The test oracle 7252 receives the traces 7212 and the environmental data 7214 and scores those outputs against a set of predefined numerical performance metrics to 7254. The performance metrics 7254 encode what may be referred to herein as a “Digital Highway Code” (DHC). Some examples of suitable performance metrics are given below.

The scoring is time-based: for each performance metric, the test oracle 7252 tracks how the value of that metric (the score) changes over time as the simulation progresses. The test oracle 7252 provides an output 7256 comprising a score-time plot for each performance metric.

The metrics 7256 are informative to an expert and the scores can be used to identify and mitigate performance issues within the tested stack 6100.

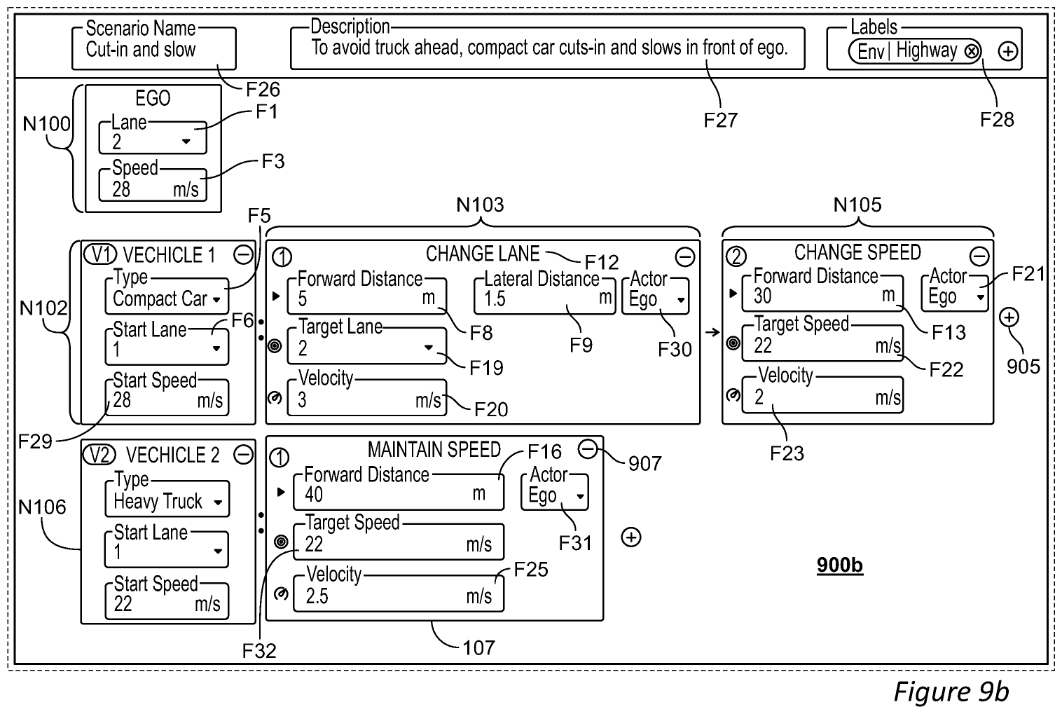

Scenarios for use by a simulation system as described above may be generated in the scenario builder described herein. Reverting to the scenario example given in FIG. 1, FIG. 8 illustrates how the interaction therein can be broken down into nodes.

FIG. 8 shows a pathway for an exemplary cut-in manoeuvre which can be defined as an interaction herein. In this example, the interaction is defined as three separate interaction nodes. A first node may be considered as a “start manoeuvre” node which is shown at point N1. This node defines a time in seconds up to the interaction point and a speed of the challenger vehicle. A second node N2 can define a cut-in profile which is shown diagrammatically by a two-headed arrow and a curved part of the path. The node is labelled N2. This node can define the lateral velocity Vy for the cut-in profile, with a cut-in duration and change of speed profile. As will be described later, a user may adjust acceleration and jerk values if they wish. A node N3 is an end manoeuvre and defines a time in seconds from the interaction point and a speed of the challenger vehicle. As described later, a node container may be made available to a user to have option to configure start and end points of the cut-in manoeuvre and to set the parameters.

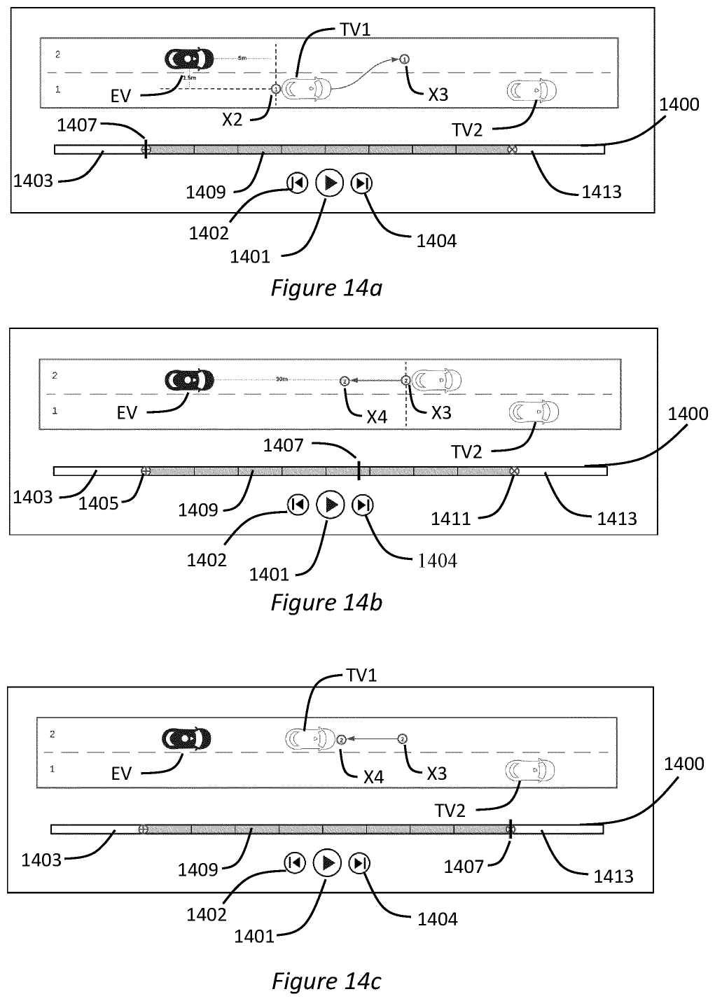

FIG. 13 shows the user interface 900a of FIG. 9a, comprising a road toggle 901 and an actor toggle 903. In FIG. 9a, the actor toggle 903 had been selected, thus populating the user interface 900a with features and input fields configured to parametrise the dynamic layer of the simulation environment, such as the vehicles to be simulated and the behaviours thereof. In FIG. 13, the road toggle 901 has been selected. As a result of this selection, the user interface 900a has been populated with features and input fields configured to parametrise the static layer of the simulation environment, such as the road layout. In the example if FIG. 13, the user interface 900a comprises a set of pre-set road layouts 1301. Selection of a particular pre-set road layout 1301 from the set thereof causes the selected road layout to be displayed in the user interface 900a, in this example in the lower portion of the user interface 900a, allowing further parametrisation of the selected road layout 1301. Radio buttons 1303 and 1305 configured to, upon selection, parametrise the side of the road on which simulated vehicles will move. Upon selection of the left-hand radio button 1303, the system will configure the simulation such that vehicles in the dynamic layer travel on the left-hand-side of the road defined in the static layer. Equally, upon selection of the right-hand radio button 1305, the system will configure the simulation such that vehicles in the dynamic layer travel on the right-hand-side of the road defined in the static layer. Selection of a particular radio button 1303 or 1305 may in some embodiments cause automatic deselection of the other such that contraflow lanes are not configurable.

The user interface 900a of FIG. 13 further displays an editable road layout 1306 representative of the selected pre-set road layout 1301. The editable road layout 1306 has associated therewith a plurality of width input fields 1309, each particular width input field 1309 associated with a particular lane in the road layout. Data may be entered to a particular width input field 1309 to parametrise the width of its corresponding lane. The lane width is used to render the scenario in the scenario editor, and to run the simulation at runtime.

The editable road layout 1306 also has an associated curvature field 1313 configured to modify the curvature of the selected pre-set road layout 1301. In the example of FIG. 13, the curvature field 1313 is shown as a slider. By sliding the arrow along the bar, the curvature of the road layout may be editable.

Additional lanes may be added to the editable road layout 1306 using a lane creator 1311. In the example of FIG. 13, in the case that left-hand travel implies left-to-right travel on the displayed editable road layout 1306, one or more lane may be added to the left-hand-side of the road by selecting the lane creator 1311 found above the editable road layout 1306. Equally, one or more lane may be added to the right-hand-side of the road by selecting the lane creator 1311 found below the editable road layout 1311. For each lane added to the editable road layout 1306, an additional width input field 1309 configured to parametrise the width of that new lane is also added.

Lanes found in the editable road layout 1306 may also be removed upon selection of a lane remover 1307, each lane in the editable road layout having a unique associated lane remover 1307. Upon selection of a particular lane remover 1307, the lane associated with that particular lane remover 1307 is removed; the width input field 1309 associated with that lane is also removed.

In this way, an interaction can be defined by a user relative to a particular layout. The path of the challenger vehicle can be set to continue before the manoeuvre point at constant speed required for the start of the manoeuvre. The path of the challenger vehicle after the manoeuvre ends should continue at constant speed using a value reached at the end of the manoeuvre. A user can be provided with options to configure the start and end of the manoeuvre points and to view corresponding values at the interaction point. This is described in more detail below.

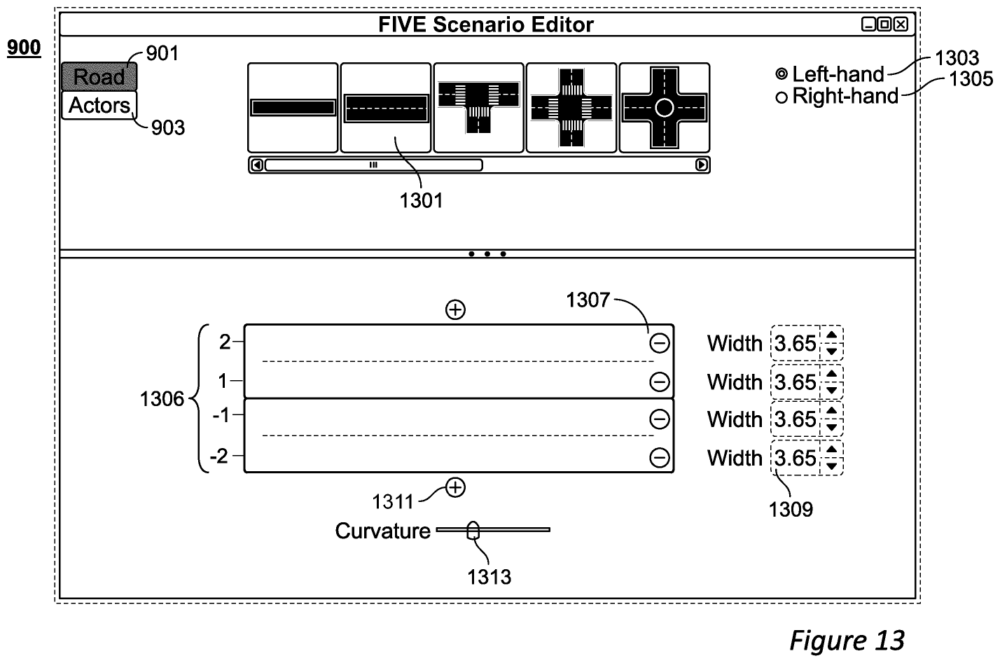

By constructing a scenario using a sequence of defined interactions, it is possible to enhance what can be done in the analysis phase post simulation with the created scenarios. For example, it is possible to organise analysis output around an interaction point. The interaction can be used as a consistent time point across all explored scenarios with a particular manoeuvre. This provides a single point of comparative reference from which a user can then view a configurable number of seconds of analysis output before and after this point (based on runtime duration). FIG. 12 shows a framework for constructing a general user interface 900a at which a simulation environment can be parametrised. The user interface 900a of FIG. 12 comprises a scenario name field 1201 wherein the scenario can be assigned a name. A description of the scenario can further be entered into a scenario description field 1203, and metadata pertaining to the scenario, date of creation for example, may be stored in a scenario metadata field 1205.

An ego object editor node N100 is provided to parameterise an ego vehicle, the ego node N100 comprising fields 1202 and 1204 respectively configured to define the ego vehicle's interaction point lane and interaction point speed with respect to the selected static road layout.

A first actor vehicle can be configured in a vehicle 1 object editor node N102, the node N102 comprising a starting lane field 1206 and a starting speed field 1214, respectively configured to define the starting lane and starting speed of the corresponding actor vehicle in the simulation. Further actor vehicles, vehicle 2 and vehicle 3, are also configurable in corresponding vehicle nodes N106 and N108, both nodes N106 and N108 also comprising a starting lane field 1206 and a starting speed field 1214 configured for the same purpose as in node N102 but for different corresponding actor vehicles. The user interface 900a of FIG. 12 also comprises an actor node creator 905b which, when selected, creates an additional node and thus creates an additional actor vehicle to be executed in the scenario. The newly created vehicle node may comprise fields 1206 and 1214, such that the new vehicle may be parametrised similarly to the other objects of the scenario.

In some embodiments, the vehicle nodes N102, N106 and N108 of the user interface 900a may further comprise a vehicle selection field F5, as described later with reference to FIG. 9a.

For each actor vehicle node N102, N106, N108, a sequence of associated action nodes may be created and assigned thereto using an action node creator 905a, each vehicle node having its associated action node creator 905a situated (in this example) on the extreme right of that vehicle node's row. An action node may comprise a plurality of fields configured to parametrise the action to be performed by the corresponding vehicle when the scenario is executed or simulated. For example, vehicle node N102 has an associated action node N103 comprising an interaction point definition field 1208, a target lane/speed field 1210, and an action constraints field 1212. The interaction point definition field 1208 for node N103 may itself comprise one or more input fields capable of defining a point on the static scene topology of the simulation environment at which the manoeuvre is to be performed by vehicle 1. Equally, the target lane/speed field 1210 may comprise one or more input fields configured to define the speed or target lane of the vehicle performing the action, using the lane identifiers. The action constraints field 1212 may comprise one or more input fields configured to further define aspects of the action to be performed. For example, the action constraints field 1212 may comprise a behaviour selection field 909, as described with reference to FIG. 9a, wherein a manoeuvre or behaviour type may be selected from a predefined list thereof, the system being configured upon selection of a particular behaviour type to populate the associated action node with the input fields required to parametrise the selected manoeuvre or behaviour type. In the example of FIG. 12, vehicle 1 has a second action node N105 assigned to it, the second action node N105 comprising the same set of fields 1208, 1210, and 1212 as the first action node N103. Note that a third action node could be added to the user interface 900a upon selection of the action node creator 905a situated on the right of the second action node N105.

The example of FIG. 12 shows a second vehicle node N106, again comprising a starting lane field 1206 and a starting speed field 1214. The second vehicle node N106 is shown as having three associated action nodes N107, N109, and N111, each of the three action nodes comprising the set of fields 1208, 1210 and 1212 capable of parametrising their associated actions. An action node creator 905a is also present on the right-hand side of action node N111, selection of which would again create an additional action node configured to parametrise further behaviour of vehicle 2 during simulation.

A third vehicle node N108, again comprising a starting lane field 1206 and a starting speed field 1214, is also displayed, the third vehicle node N108 having only one action node N113 assigned to it. Action node N113 again comprises the set of fields 1208, 1210 and 1212 capable of parametrising the associated action, and a second action node could be created upon selection of the action node creator 905a found to the right of action node N113.

Action nodes and vehicle nodes alike also have a selectable node remover 907 which, when selected, removes the associated node from the user interface 900a, thereby removing the associated action or object from the simulation environment. Further, selection of a particular node remover 907 may cause nodes subsidiary to or dependent upon that particular node to also be removed. For example, selection of a node remover 907 associated with a vehicle node (such as N106) may cause the action nodes (such as N107) associated with that vehicle node to be automatically removed without selection of the action node's node remover 907.

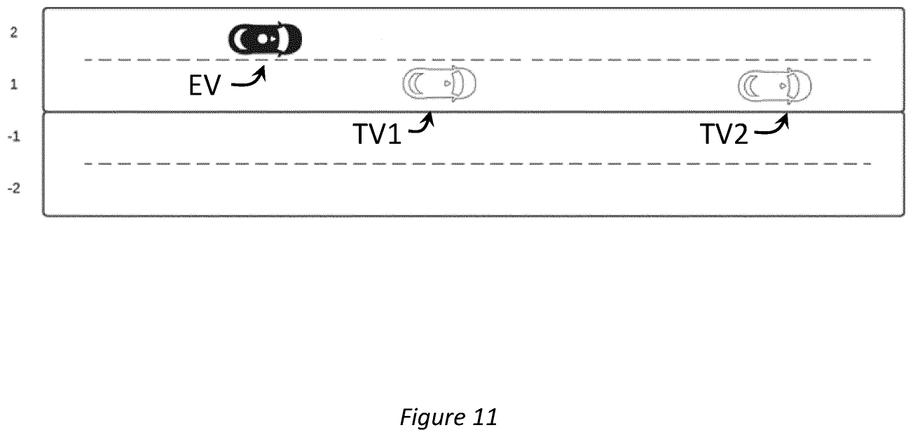

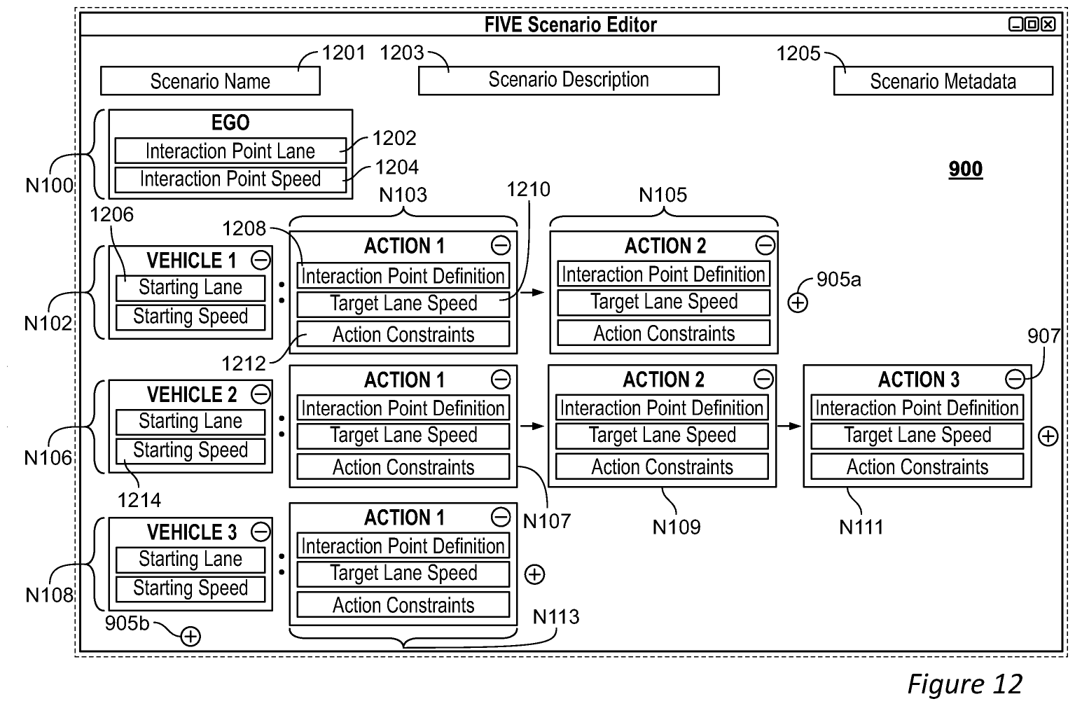

Upon entry of inputs to all relevant fields in the user interface 900a of FIG. 12, a user may be able to view a pre-simulation visual representation of their simulation environment, such as described in the following with reference to FIGS. 10a, 10b and 11 for the inputs made in FIG. 9a. Selection of a particular node may then display the parameters entered therein to appear as data overlays on the associated visual representation, such as in FIGS. 10a and 10b.

FIG. 9a illustrates one particular example of how the framework of FIG. 12 may be utilized to provide a set of nodes for defining a cut-in interaction. Each node may be presented to a user on a user interface of the editing tool to allow a user to configure the parameters of the interaction. N100 denotes a node to define the behaviour of the ego vehicle. A lane field F1 allows a user to define a lane on the scene topology in which the ego vehicle starts. A maximum acceleration field F2 allows the user to configure a maximum acceleration using up and down menu selection buttons. A speed field F3 allows a fixed speed to be entered, using up and down buttons. A speed mode selector allows speed to be set at a fixed value (shown selected in node N100 in FIG. 9a) or a percent of speed limit. The percent of speed limit is associated with its own field F4 for setting by a user. Node 102 describes a challenger vehicle. It is selected from an ontology of dynamic objects using a dropdown menu shown in field F5. The lane in which the challenger vehicle is operating is selected using a lane field F6. A cut-in interaction node N103 has a field F8 for defining the forward distance dx0 and a field F9 for defining the lateral distance dy0. Respective fields F10 and F11 are provided for defining the maximum acceleration for the cut-in manoeuvre in the forward and lateral directions.

The node N103 has a title field F12 in which the nature of the interaction can be defined by selecting from a plurality of options from a dropdown menu. As each option is selected, relevant fields of the node are displayed for population by a user for parameters appropriate to that interaction.

The pathway of a challenger vehicle is also subject to a second node N105 which defines a speed change action. The node N105 comprises a field F13 for configuring the forward distance of the challenger vehicle at which to instigate the speed change, a field F14 for configuring the maximum acceleration and respective speed limit fields F15 and F16 which behave in a manner described with reference to the ego vehicle node N100.

Another vehicle is further defined using object node N106 which offers the same configurable parameters as node N102 for the challenger vehicle. The second vehicle is associated with a lane keeping behaviour which is defined by a node N107 having a field F16 for configuring a forward distance relative to the ego vehicle and a field F17 for configuring a maximum acceleration.

FIG. 9a further shows a road toggle 901 and an actor toggle 903. The road toggle 901 is a selectable feature of the user interface 900a which, when selected, populates the user interface 900a with features and input fields configured to parametrise the static layer of the simulation environment, such as the road layout (see description of FIG. 13). Actor toggle 903 is a selectable feature of the user interface 900a which, when selected, populates the user interface 900a with features and input fields configured to parametrise the dynamic layer of the simulation environment, such as the vehicles to be simulated and the behaviours thereof.

As described with reference to FIG. 12, a node creator 905 is a selectable feature of the user interface 900a which, when selected, creates an additional node capable of parametrising additional aspects of the simulation environment's dynamic layer. The action node creator 905a may be found on the extreme right of each actor vehicle's row. When selected, such action node creators 905a assign an additional action node to their associated actor vehicle, thereby allowing multiple actions to be parametrised for simulation. Equally, a vehicle node creator 905b may be found beneath the bottom-most vehicle node. Upon selection, the vehicle node creator 905b adds an additional vehicle or other dynamic object to the simulation environment, the additional dynamic object further configurable by assigning one or more action nodes thereto using an associated action node creator 905a. Action nodes and vehicle nodes alike may have a selectable node remover 907 which, when selected, removes the associated node from the user interface 900a, thereby removing the associated behaviour or object from the simulation environment. Further, selection of a particular node remover 907 may cause nodes subsidiary to or dependent upon that particular node to also be removed. For example, selection of a node remover 907 associated with a vehicle node (such as N106) may cause the action nodes (such as N107) associated with that vehicle node to be automatically removed without selection of the action node's node remover 907.

Each vehicle node may further comprise a vehicle selection field F5, wherein a particular type of vehicle may be selected from a predefined set thereof, such as from a drop-down list. Upon selection of a particular vehicle type from the vehicle selection field F5, the corresponding vehicle node may be populated with further input fields configured to parametrise vehicle type-specific parameters. Further, selection of a particular vehicle may also impose constraints on corresponding action node parameters, such as maximum acceleration or speed.

Each action node may also comprise a behaviour selection field 909. Upon selection of the behaviour selection field 909 associated with a particular action node (such as N107), the node displays, for example on a drop-down list, a set of predefined behaviours and/or manoeuvre types that are configurable for simulation. Upon selection of a particular behaviour from the set of predefined behaviours, the system populates the action node with the input fields necessary for parametrisation of the selected behaviour of the associated vehicle. For example, the action node N107 is associated with an actor vehicle TV2 and comprises a behaviour selection field 909 wherein the ‘lane keeping’ behaviour has been selected. As a result of this particular selection, the action node N107 has been populated with a field F16 for configuring forward distance of the associated vehicle TV2 from the ego vehicle EV and a maximum acceleration field F17, the fields shown allowing parametrisation of the actor vehicle TV2's selected behaviour-type.

FIG. 9b shows another embodiment of the user interface of FIG. 9a. FIG. 9b comprises the same vehicle nodes N100, N102 and N106, respectively representing an ego vehicle EV, a first actor vehicle TV1 and a second actor vehicle TV 2. The example of 9b gives a similar scenario to that of FIG. 9a, but where the first actor vehicle TV1, defined by node N102, is performing a ‘lane change’ manoeuvre rather than a ‘cut-in’ manoeuvre, where the second actor vehicle TV2, defined by node N106, is performing a ‘maintain speed’ manoeuvre rather than a ‘lane keeping’ manoeuvre, and is defined as a ‘heavy truck’ as opposed to a ‘car;’ several exemplary parameters entered to the fields of user interface 900b also differ from those of user interface 900a.

The user interface 900b of FIG. 9b comprises several features that are not present in the user interface 900a of FIG. 9a. For example, the actor vehicle nodes N102 and N106, respectively configured to parametrise actor vehicles TV1 and TV2, include a start speed field F29 configured to define an initial speed for the respective vehicle during simulation. User interface 900b further comprises a scenario name field F26 wherein a user can enter one or more characters to define a name for the scenario that is being parametrised. A scenario description field F27 is also included and is configured to receive further characters and/or words that will help to identify the scenario and distinguish it from others. A labels field F28 is also present and is configured to receive words and/or identifying characters that may help to categorise and organise scenarios which have been saved. In the example of user interface 900b, field F28 has been populated with a label entitled: ‘Env|Highway.’

Several features of the user interface 900a of FIG. 9a are not present on the user interface 900b of FIG. 9b. For example, in user interface 900b of FIG. 9b, no acceleration controls are defined for the ego vehicle node N100. Further, the road and actor toggles, 901 and 903 respectively, are not present in the example of FIG. 9b; user interface 900b is specifically configured for parametrising the vehicles and their behaviours.

Furthermore, the options to define a vehicle speed as a percentage of a defined speed limit, F4 and F18 of FIG. 9a, are not available features of user interface 900b; only fixed speed fields F3 are configurable in this embodiment. Acceleration control fields, such as field F14, previously found in the speed change manoeuvre node N105, are also not present in the user interface 900b of FIG. 9b. Behavioural constraints for the speed change manoeuvre are parametrised using a different set of fields.

Further, the speed change manoeuvre node N105, assigned to the first actor vehicle TV1, is populated with a different set of fields. The maximum acceleration field F14, fixed speed field F15 and % speed limit field F18 found in the user interface 900a are not present in 900b. Instead, a target speed field F22, a relative position field F21 and a velocity field F23 are present. The target speed field F22 is configured to receive user input pertaining to the desired speed of the associated vehicle at the end of the speed change manoeuvre. The relative position field F21 is configured to define a point or other simulation entity from which the forward distance defined in field F13 is measured; the forward distance field F13 is present in both user interfaces 900a and 900b. In the example of FIG. 9b, the relative position field F21 is defined as the ego vehicle, but other options may be selectable, such as via a drop-down menu. The velocity field F23 defines a velocity or rate for the manoeuvre. Since the manoeuvre defined by node N103 is speed-dependent (as opposed to position- or lane-dependent), the velocity field F23 constrains the rate at which the target speed, as defined in field F22, can be reached; velocity field F23 therefore represents an acceleration control.

Since the manoeuvre node N103 assigned to the first actor vehicle TV1 is defined as a lane change manoeuvre in user interface 900b, the node N103 is populated with different fields to the same node in user interface 900a, which defined a cut-in manoeuvre. The manoeuvre node N103 of FIG. 9b still comprises a forward distance field F8 and a lateral distance field F9, but now further comprises a relative position field F30 configured to define the point or other simulation entity from which the forward distance of field F8 is measured. In the example of FIG. 9b, the relative position field F30 defines the ego vehicle as the reference point, though other options may be configurable, such as via selection from a drop-down menu. The manoeuvre activation conditions are thus defined by measuring, from the point or entity defined in F30, the forward and lateral distances defined in fields F8 and F9. The lane change manoeuvre node N103 of FIG. 9b further comprises a target lane field F19 configured to define the lane occupied by the associated vehicle after performing the manoeuvre, and a velocity field F20 configured to define a motion constraint for the manoeuvre.

Since the manoeuvre node N107 assigned to the second actor vehicle TV2 is defined as a ‘maintain speed’ manoeuvre in FIG. 9b, node 107 of FIG. 9b is populated with different fields to the same node in user interface 900a, which defined a ‘maintain speed’ manoeuvre. The manoeuvre node N107 of FIG. 9b still comprises a forward distance field F16, but does not include the maximum acceleration field F17 that was present in FIG. 9a. Instead, node N107 of FIG. 9b comprises a relative position field F31, which acts to the same purpose as the relative position fields F21 and F30 and may similarly be editable via a drop-down menu. Further, a target speed field F32 and velocity field F25 are included. The target speed field F32 is configured to define a target speed to be maintained during the manoeuvre. The velocity field F25 defines a velocity or rate for the manoeuvre. Since the manoeuvre defined by node N105 is speed-dependent (as opposed to position- or lane-dependent), the velocity field F25 constrains the rate at which the target speed, as defined in field F32, can be reached; velocity field F25 therefore represents an acceleration control.

The fields populating nodes N103 and N107 differ between FIGS. 9a and 9b because the manoeuvres defined therein are different. However, it should be noted that should the manoeuvre-type defined in those nodes be congruent between FIGS. 9a and 9b, the user interface 900b may still populate each node differently than user interface 900a.

The user interface 900b of FIG. 9b comprises a node creator button 905, similarly to the user interface 900a of FIG. 9a. However, the example of FIG. 9b does not show a vehicle node creator 905b, which was a feature of the user interface 900a of FIG. 9a.

In the example of FIG. 9b, the manoeuvre-type fields, such as F12, may not be editable fields. In FIG. 9a, field F12 is an editable field whereby upon selection of a particular manoeuvre type from a drop-down list thereof, the associated node is populated with the relevant input fields for parametrising the particular manoeuvre type. Instead, in the example of FIG. 9b, a manoeuvre type may be selected upon creation of the node, such as upon selection of a node creator 905.

FIGS. 10a and 10b provide examples of the pre-simulation visualisation functionality of the system. The system is able to create a graphical representation of the static and dynamic layers such that a user can visualise the parametrised simulation before running it. This functionality significantly reduces the likelihood that a user unintentionally programs the desired scenario incorrectly.

The user can view graphical representations of the simulation environment at key moments of the simulation, for example at an interaction condition point, without running the simulation and having to watch it to find that there was a programming error. FIGS. 10a and 10b also demonstrate a selection function of the user interface 900a of FIG. 9a. One or more node may be selectable from the set of nodes comprised within FIG. 9a, selection of which causes the system to make a data overlay of that node's programmed behaviour on the graphical representation of the simulation environment.

For example, FIG. 10a shows the graphical representation of the simulation environment programmed in the user interface 900a of FIG. 9a, wherein the node entitled, ‘vehicle 1’ has been selected. As a result of this selection, the parameters and behaviours assigned to vehicle 1 TV1 are visible as data overlays on FIG. 10a. The symbols X2 mark the points at which the interaction conditions defined for node N103 are met, and, since the points X2 are defined by distances entered to F8 and F9 rather than coordinates, the symbol X1 defines the point from which the distances parametrised in F8 and F9 are measured (all given examples use the ego vehicle EV to define the X1 point). An orange dotted line 1001 marked ‘20 m’ also explicitly indicates the longitudinal distance between the ego vehicle EV and vehicle 1 TV1 at which the manoeuvre is activated (the distance between X1 and X2).

The cut-in manoeuvre parametrised in node N103 is also visible as a curved orange line 1002 starting at an X2 symbol and finishing at an X4 symbol, the symbol type being defined in the upper left corner of node N103. Equally, the speed change manoeuvre defined in node N105 is shown as an orange line 1003 starting where the cut-in finished, at the X4 symbol, and finishing at an X3 symbol, the symbol type being defined in the upper left corner of node N105.

Upon selection of the ‘vehicle 2’ node N106, the data overlays assigned to vehicle 2 TV2 are shown, as in FIG. 10b. Note that the FIGS. 10a and 10b show identical instances in time, differing only in the vehicle node that has been selected in the user interface 900a of FIG. 9a, and therefore in the data overlays present. By selecting the vehicle 2 node N106, a visual representation of the ‘lane keeping’ manoeuvre, assigned to vehicle 2 TV2 in node N107, is present in FIG. 10b. The activation condition for this vehicle's manoeuvre, as defined in F16, is shown as a blue dotted line 1004 overlaid on FIG. 10b; also present are X2 and X1 symbols, respectively representing the points at which the activation conditions are met and the point from which the distances defining the activation conditions are measured. The lane keeping manoeuvre is shown as a blue arrow 1005 overlaid on FIG. 10b, the end point of which is again marked with the symbol defined in the upper left corner of node N107, in this case, an X3 symbol.

In some embodiments, it may be possible to simultaneously view data overlays pertaining to multiple vehicles, or to view data overlays pertaining to just one manoeuvre assigned to a particular vehicle, rather than all manoeuvres assigned thereto.

In some embodiments, it may also be possible to edit the type of symbol used to define a start or end point of the manoeuvres, in this case, the symbols in the upper left corner of the FIG. 9a action nodes being a selectable and editable feature of the user interface 900.

In some embodiments, no data overlays are shown. FIG. 11 shows the same simulation environment as configured in the user interface 900 of FIG. 9a, but wherein none of the nodes is selected. As a result, none of the data overlays seen in FIG. 10a or 10b is present; only the ego vehicle EV, vehicle 1 TV1, and vehicle 2 TV2 are shown. What is represented by FIGS. 10a, 10b and 11 is constant; only the data overlays have changed.

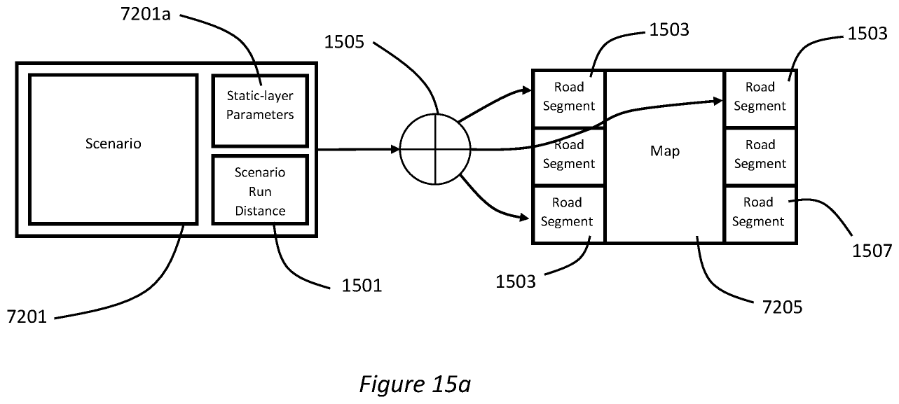

FIGS. 14a, 14b and 14c show pre-simulation graphical representations of an interaction scenario between three vehicles: EV. TV1 and TV2, respectively representing an ego vehicle, a first actor vehicle and a second actor vehicle. Each figure also includes a scrubbing timeline 1400 configured to allow dynamic visualisation of the parametrised scenario prior to simulation. For all of FIGS. 14a, 14b and 14c, the node for vehicle TV1 has been selected in the node editing user interface (such as FIG. 9b) such that data overlays pertaining to the manoeuvres of vehicle TV1 are shown on the graphical representation.

The scrubbing timeline 1400 includes a scrubbing handle 1407 which may be controlled in either direction along the timeline. The scrubbing timeline 1400 also has associated with it a quantity of playback controls 1401, 1402 and 1404: a play button 1401, a rewind button 1402 and a fast-forward button 1404. The play button may be configured upon selection to play a dynamic pre-simulation representation of the parametrised scenario; playback may begin from the position of the scrubbing handle 1407 at the time of selection. The rewind button 1402 is configured to, upon selection, move the scrubbing handle 1407 in the left-hand direction, thereby causing the graphical representation to show the corresponding earlier moment in time. The rewind button 1402 may also be configured to, when selected, move the scrubbing handle 1407 back to a key moment in the scenario, such as the nearest time at which a manoeuvre began; the graphical representation of the scenario would therefore adjust to be consistent with the new point in time. Similarly, the fast-forward button 1404 is configured to, upon selection, move the scrubbing handle 1407 in the right-hand direction, thereby causing the graphical representation to show the corresponding later moment in time. The fast forward button 1404 may also be configured to, upon selection, move to a key moment in the future, such as the nearest point in the future at which a new manoeuvre begins; in such cases, the graphical representation would therefore change in accordance with the new point in time.

In some embodiments, the scrubbing timeline 1400 may be capable of displaying a near-continuous set of instances in time for the parametrised scenario. In this case, a user may be able to scrub to any instant in time between the start and end of the simulation, and view the corresponding pre-simulation graphical representation of the scenario at that instant in time. In such cases, selection of the play button 1401 may allow the dynamic visualisation to be played at such a frame rate that the user perceives a continuous progression of the interaction scenario; i.e. video playback.

The scrubbing handle 1407 may itself be a selectable feature of the scrubbing timeline 1400. The scrubbing handle 1407 may be selected and dragged to a new position on the scrubbing timeline 1400, causing the graphical representation to change and show the relative positions of the simulation entities at the new instant in time. Alternatively, selection of a particular position along the scrubbing timeline 1400 may cause the scrubbing handle 1407 to move to the point along the scrubbing timeline at which the selection was made.

The scrubbing timeline 1400 may also include visual indicators, such as coloured or shaded regions, which indicate the various phases of the parametrised scenario. For example, a particular visual indication may be assigned to a region of the scrubbing timeline 1400 to indicate the set of instances in time at which the manoeuvre activation conditions for the particular vehicle have not yet been met. A second visual indication may then denote a second region. For example, the region may represent a period of time wherein a manoeuvre is taking place, or where all assigned manoeuvres have already been performed. For example, the exemplary scrubbing timeline 1400 for FIG. 1A includes an un-shaded pre-activation region 1403, representing the period of time during which the activation conditions for the scenario are not yet met. A shaded manoeuvre region 1409 is also shown, indicating the period of time during which the manoeuvres assigned to the actor vehicles TV1 and TV2 are in progress. The exemplary scrubbing timeline 1400 further includes an un-shaded post-manoeuvre region 1413, indicating the period of time during which the manoeuvres assigned to the actor vehicles TV1 and TV2 have already been completed.

As shown in FIG. 14b, the scrubbing timeline 1400 may further include symbolic indicators, such as 1405 and 1411, which represent the boundary between scenario phases. For example, the exemplary scrubbing timeline 1400 includes a first boundary indicator 1405, which represents the instant in time at which the manoeuvres are activated. Similarly, a second boundary point 1411 represents the boundary point between the mid- and post-manoeuvre phases, 1409 and 1413 respectively. Note that the symbols used to denote boundary points in FIGS. 14a, 14b and 14c may not be the same in all embodiments.

FIGS. 14a, 14b and 14c show the progression of time for a single scenario. In FIG. 14a, the scrubbing handle 1407 is positioned at the first boundary point 1405 between the pre- and mid-interaction phases of the scenario, 1403 and 1409 respectively. As a result, the actor vehicle TV1 is shown at the position where this transition takes place: point X2. In FIG. 14b, the actor vehicle TV1 has performed its first manoeuvre (cut-in) and reached point X3. At this moment in time, actor vehicle TV1 will begin to perform its second manoeuvre: a slow down manoeuvre. Since time has passed since the activation of the manoeuvre at point X2, or the corresponding first boundary point 1405, the scrubbing handle 1407 has moved such that it corresponds with the point in time at which the second manoeuvre starts. Note that in FIG. 14b the scrubbing handle 1407 is found within the mid-manoeuvre phase 1409, as indicated by shading. FIG. 14c then shows the moment in time at which the manoeuvres are completed. The actor vehicle TV1 has reached point X4 and the scrubbing handle has progressed to the second boundary point 1411, the point at which the manoeuvres finish.

The scenario visualisation is a real-time rendered depiction of the agents (in this case, vehicles) on a specific segment of road that was selected for the scenario. The ego vehicle EV is depicted in black, while other vehicles are labelled (TV1, TV2, etc). Visual overlays are togglable on-demand, and depict start and end interaction points, vehicle positioning and trajectory, and distance from other agents. Selection of a different vehicle node in the corresponding node editing user interface, such as in FIG. 9b, control the vehicle or actor for which visual overlays are shown.

The timeline controller allows the user to play through the scenario interactions in real-time (play button), jump from one interaction point to the next (skip previous/next buttons) or scrub backwards or forwards through time using the scrubbing handle 1407. The circled “+” designates the first interaction point in the timeline, and the circled “×” represents the final end interaction point. This is all-inclusive for agents in the scenario; that is, the circled “+” denotes the point in time at which the first manoeuvre for any agent in the simulation begins, and the circled “×” represents the end of the last manoeuvre for any agent in the simulation.

When playing through the timeline, the agent visualisation will depict movement of the agents as designated by their scenario actions. In the example provided by FIG. 14a, the TV1 agent has its first interaction with the ego EV at the point it is 5 m ahead and 1.5 m lateral distance from the ego, denoted point X2. This triggers the first action (designated by the circled “1”) where TV1 will perform a lane change action from lane 1 to lane 2, with speed and acceleration constraints provided in the scenario. When that action has completed, the agent will move on to the next action. The second action, designated by the circled “2” in FIG. 14b, will be triggered when TV1 is 30 m ahead of ego, which is the second interaction point. TV1 will then perform its designated action of deceleration to achieve a specified speed. When it reaches that speed, as shown in FIG. 14c, the second action is complete. As there are no further actions assigned to this agent, it will perform no further manoeuvres.

The example images depict a second agent in the scenario (TV2). This vehicle has been assigned the action of following lane 2 and maintaining a steady speed. As this visualisation viewpoint is a birds-eye top-down view of the road, and the view is tracking the ego, we only see agent movements that are relative to each other, so we do not see TV2 move in the scenario visualisation.

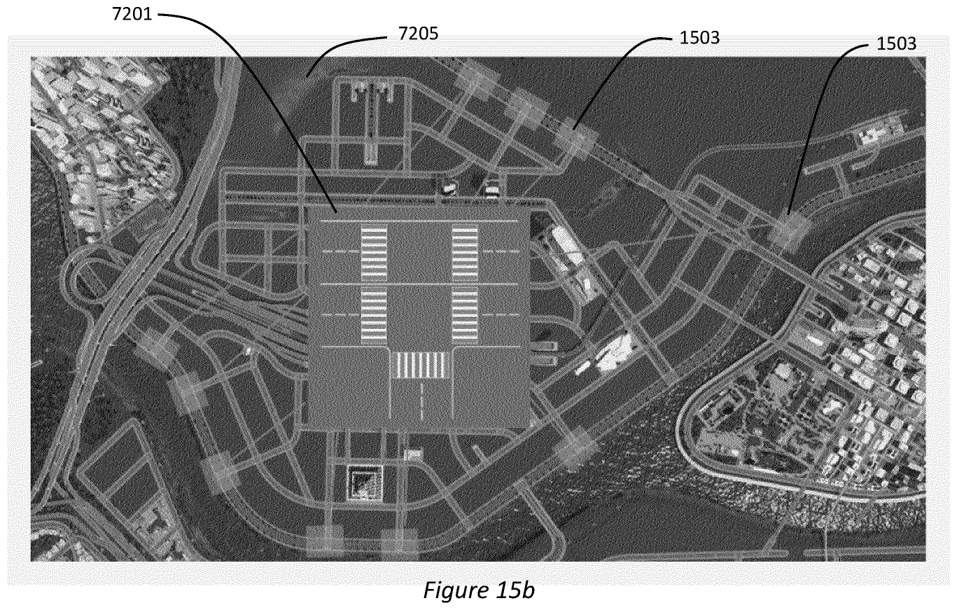

FIG. 15a is a highly schematic diagram of the process whereby the system recognises all instances of a parametrised static layer 7201a of a scenario 7201 on a map 7205. The parametrised scenario 7201, which may also include data pertaining to dynamic layer entities and the interactions thereof, is shown to comprise data subgroups 7201a and 1501, respectively pertaining to the static layer defined in the scenario 7201, and the distance requirements of the static layer. By way of example, the static layer parameters 7201a and the scenario run distance 1501 may, when combined, define a 100 m section of a two-lane road which ends at a ‘T-junction’ of a four-lane ‘dual carriageway.’

The identification process 1505 represents the system's analysis of one or more maps stored in a map database. The system is capable of identifying instances on the one or more maps which satisfy the parametrised static layer parameters 7201a and scenario run distance 1501. The maps 7205 which comprise suitable instances of the parametrised road segment may then be offered to a user for simulation.

The system may search for the suitable road segments by comparing the parametrised static layer criteria to existing data pertaining to the road segments in each map. In this case, the system will differentiate a subset of suitable road segments 1503 from a remaining subset of unsuitable road segments 1507.

FIG. 15b depicts an exemplary map 7205 comprising a plurality of different types of road segment. As a result of a user parametrising a static layer 7201a and a scenario run distance 1501 as part of a scenario 7201, the system has identified all road segments within the map 7205 which are suitable examples of the parametrised road layout. The suitable instances 1503 identified by the system are highlighted in blue in FIG. 15b.

1. A computer implemented method of generating a scenario to be run in a simulation environment for testing the behaviour of an autonomous vehicle, the method comprising:
rendering on a display of a computer device, an image of a static scene topology;
rendering on the display an object editing node comprising a set of input fields for receiving user input, the object editing node for parameterizing an interaction of a challenger object relative to an ego object;
receiving into the input fields of the object editing node user input defining at least one temporal or relational constraint of the challenger object relative to the ego object, the at least one temporal or relational constraints defining an interaction point of a defined interaction stage between the ego object and the challenger object;
storing the set of constraints and defined interaction stage in an interaction container in a computer memory of the computer system; and
generating a scenario to be run in a simulation environment, the scenario comprising the defined interaction stage executed on the static scene topology at the interaction point.

2. The method of claim 1 wherein the set of input fields comprises a field for receiving an indication of a defined interaction for the challenger object to execute in the scenario.

3. The method of claim 2 wherein the set of input fields comprises an input field for receiving an indication of the manner in which the defined interaction is to be executed in the scenario.

4. The method of claim 1 wherein the set of input fields comprises a field for receiving an indication of a behavior of the challenger object at the interaction point.

5. The method of claim 1 wherein the set of input fields comprises a field for receiving an indication of an object type.

6. The method of claim 1 wherein one or more of the input fields comprises a menu of predetermined options, enabling selection by a user of one of the predetermined options to parameterize the challenger object.

7. The method of claim 1 wherein the static scene topology comprises a road layout.

8. The method of claim 1 comprising the step of selecting a static scene topology from a library of predefined scene topologies, and rendering the selected scene topology on the display.

9. The method of claim 7, wherein the road layout comprises one or more driving lane, and wherein the set of input fields comprises a field for receiving an indication of lane driving behavior of the challenger object.

10. The method of claim 9 comprising assigning lane identifiers to each of the one or more driving lane of the road layout, and receiving an association via the object editing node of an identified lane and the challenger object at the interaction point.

11. The method of claim 1 comprising rendering on the display a second object editing node for further parameterizing the challenger object and receiving user input into fields of the second editing node to define a further stage of the defined interaction each interaction defined as a respective sequence of stages, wherein the generated scenario comprises the sequence of interaction stages executed by the challenger object.

12. The method of claim 1 comprising rendering on the display an ego object editing node for parameterizing the ego vehicle in the scenario by receiving a starting condition of the ego vehicle and behaviour constraints for the ego vehicle prior to the interaction point.

13. The method of claim 1 wherein the challenger object comprises a dynamic actor, wherein the interaction defines an action to be taken by the dynamic actor at a time and location in the scene relative to the ego vehicle defined by the at least one temporal or relational constraint.

14. The method of claim 13 wherein the action to be taken by the challenger object comprises a manoeuvre or behaviour.

15. The method of claim 1 comprising storing the interaction container with an interaction container identifier which identifies the defined interaction and the scene topology.

16. The method of claim 14 wherein the manoeuvre comprises one of cut-in; cut-out; and switch lanes.

17. The method of claim 14 wherein the behavior comprises one of: deceleration, acceleration, travel at fixed speed and follow lane.

18. A computer system for generating a scenario to be run in a simulation environment for testing the behaviour of an autonomous vehicle, the system comprising:
computer memory;
a user interface configured to display an image of a static scene topology;
a processor configured to render on the user interface an object editing node comprising a set of input fields for receiving user input, the object editing node for parameterizing an interaction of a challenger object relative to an ego object;
the user interface configured to receive into the input fields of the object editing node user input defining at least one temporal or relational constraint of the challenger object relative to the ego object, the at least one temporal or relational constraints defining an interaction point of a defined interaction stage between the ego object and the challenger object;
the processor configured to store the at least one constraint and defined interaction stage in an interaction container in the computer memory of the computer system; and
to generate a scenario to be run in a simulation environment, the scenario comprising the defined interaction stage executed on the static scene topology at the interaction point.

19. Non transitory computer readable media on which is stored computer readable instructions which when executed by one or more processor carry out a method comprising:
rendering on a display of a computer device, an image of a static scene topology;
rendering on the display an object editing node comprising a set of input fields for receiving user input, the object editing node for parameterizing an interaction of a challenger object relative to an ego object;
receiving into the input fields of the object editing node user input defining at least one temporal or relational constraint of the challenger object relative to the ego object, the at least one temporal or relational constraints defining an interaction point of a defined interaction stage between the ego object and the challenger object;
storing the set of constraints and defined interaction stage in an interaction container in a computer memory of the computer system; and
generating a scenario to be run in a simulation environment, the scenario comprising the defined interaction stage executed on the static scene topology at the interaction point.

20. The computer system of claim 18 wherein the road layout comprises one or more driving lane, and wherein the set of input fields comprises a field for receiving an indication of lane driving behavior of the challenger object.
